(19) United States
(12) Patent Application Publication
(10) Pub. No.: US 2014/0290390 A1
(43) Pub. Date: Oct. 2, 2014

(54) SYSTEMS AND METHODS FOR RESISTIVE MICROCRACKED PRESSURE SENSOR

(71) Applicant: Arizona Board of Regents, a Body Corporate of the State of Arizona, Action for and on Behalf of AZ, Scottsdale, AZ (US)

(72) Inventors: Oliver Graudejus, Scottsdale, AZ (US); James Abbas, Scottsdale, AZ (US)

(73) Assignee: Arizona Board of Regents, a Body Corporate of the State of Arizona, Action for and on Behalf of AZ, Scottsdale, AZ (US)

(21) Appl. No.: 14/243,563

(22) Filed: Apr. 2, 2014

Related U.S. Application Data
(60) Provisional application No. 61/807,540, filed on Apr. 2, 2013.

(51) Int. Cl. G01L 1/22; H05K 3/28

(52) U.S. Cl. CPC G01L 1/22; H05K 3/284
USPC 73/862.627; 29/846; 29/593

(57) ABSTRACT

Embodiments of a resistive microcracked pressure sensor having a metal stack with a metallic conductor encapsulated within an elastomer substrate and related method of manufacture are disclosed. During manufacture, the metallic conductor forms a plurality of microcracks that increase the overall resistance of the metallic conductor. The microcracks in the metallic conductor allow greater magnitudes of normal and shear forces to be applied to the pressure sensor without fracturing metallic conductor.

### CROSS REFERENCE TO RELATED APPLICATIONS

This is a non-provisional application that claims benefit to U.S. provisional patent application Ser. No. 61/807,540, filed on Apr. 2, 2013 and is herein incorporated by reference in its entirety.

### FIELD

The present document relates to systems and methods for a flexible pressure sensor that measures normal and shear forces, and in particular to systems and methods for a resistive microcracked pressure sensor that includes a metallic conductor having a plurality of microcracks that are formed during manufacture for increasing the change in resistance of the metallic conductor to high magnitude forces.

### BACKGROUND

The field of biomimetic engineering is rapidly expanding and holds great promise in a number of fields, but perhaps most strongly in the area of biomedical engineering that deals with medical rehabilitation. In designing systems to replace and/or interact with biological systems, a biomimetic approach not only may yield good performance, but it may also contribute to the field of biomimetic engineering by developing skin-like sensate materials.

Loss of sensation in the feet leads to secondary complications for individuals suffering from diabetes, stroke, and spinal cord injury. The loss of sensation is due either to damage to somatosensory neurons in the periphery (e.g., in the case of diabetes) or by damage to the somatosensory central nervous system pathways caused by traumatic injury or cerebrovascular accident. Impairments to motor control can also result from spinal cord or brain injury, stroke, Parkinson's disease, multiple sclerosis, or cerebral palsy. Systems that provide sensory substitution may be able to avert or reduce the secondary complications due to loss of sensation. In addition, systems that provide neuromotor assistance by neuromuscular stimulation during locomotion may improve the safety or efficiency of gait of an individual. Both types of applications require the use of a sensor that is reliable and biocompatible.

Measurements of plantar pressure can provide signals that are useful either in systems that provide sensory substitution or in systems that provide neuromotor assistance. These strategies for treatment of peripheral neuropathy or neuromotor disability require a sensor to measure plantar pressure patterns on the sole of the foot. The sensor should provide measures of pressure at critical locations under the sole of the foot (e.g., heel, metatarsals) and should be reliable and durable to enable everyday use. For applications that would utilize body-worn technology, the sensor system should be made of a material that is suitable for use in an insole inserted in the shoe. The primary design issues here would be that the material should be suitable for skin contact (i.e., should not cause any adverse reaction with the skin) and the elastic modulus of the material should be comparable to that of the sole of the foot in order to facilitate the distribution of pressure and for comfort of the individual.

For applications that would utilize implanted technology, the biocompatibility and mechanical interface issues still remain, yet the demands are more pronounced. Plantar pressure can be measured by mechanical, optical, acoustical, pneumatic, and electrical means. Measuring pressure by electrical means is the most widely used technology because of the robustness and ease of fabrication of the sensor as well as the accuracy and sensitivity of the measurement. Most plantar pressure sensors that use electrical means fall into one of three categories: resistive, piezoelectric or capacitive. In these sensors, an applied pressure causes a change in resistance (in a conductor), in voltage (in a piezoelectric material) or in capacitance (in a capacitor). Pressure sensors that use the change in resistance of a conducting material as a method of transduction often use designs akin to conventional strain gage. In resistive metallic pressure gages, the pressure applied to a metallic conductor results in a change in its dimensions due to Poisson compression which causes the resistance to increase.

Another type of resistive pressure gage uses a conductive elastomer as a resistor. In these types of pressure gages, silicone is loaded with a conductive material such as carbon. Pressure applied to the surface causes the distance between the carbon particles to decrease, thereby reducing the resistance of the elastomer. However, the sensitivity of this pressure sensor decreases significantly and shows a large hysteresis when the applied pressure is above 200 kPa. In piezoresistive pressure gages, pressure applied to a semiconductor strains the lattice which increases the mobility of the charge carriers, thereby reducing the resistance. In piezoelectric pressure gages, pressure applied to a piezoelectric material induces a voltage across the material by separating charges. The first plantar pressure measurement using this technology was reported in 1975. It's been known that the charge, and hence the voltage, decreases over time due to leakage, which is why piezoelectric transducers are better suited for dynamic rather than static measurements.

In capacitive pressure gages, the changes in the capacitance of a capacitor may be measured. In particular, an applied pressure compresses the dielectric, i.e., which reduces the distance between the metal electrodes of the gage, and hence increases the capacitance. Capacitive pressure gages have been used for plantar pressure measurements for a long time. A recently developed capacitive pressure sensor consists of four air-gap capacitors that are embedded in a silicone matrix. This pressure sensor is capable of measuring both normal and shear forces of up to 50 kPa. However, this is not sufficient because the forces that need to be measured by plantar pressure sensors usually exceed 1 MPa. In another type of capacitive pressure gage, the change in capacitance between two metal plates on a silicone substrate with an air gap in between was monitored. The capacitance of this sensor changes linearly with the applied pressure in the range of 0 to 160 kPa. The drawbacks of this method are that (a) the capacitance changes only by about 10% over the investigated pressure range, i.e., the sensor is not very sensitive, (b) the pressure range is low (only up to 160 kPa), and (c) no shear force measurements can be carried out using this system.

While great progress has been made over the last 10 years in data acquisition, transmission and analysis, progress on the sensor itself has been largely incremental. In particular, none of the commercially available plantar pressure sensors are suitable for long-term measurements. In addition, all in-shoe pressure sensors are just that, to be used only in the shoe. A pressure sensor that could be permanently implanted into the sole of the foot could greatly improve the usability and reliability of the system and it could enable usage in a broader range of medical applications. Besides not being implantable, most current pressure sensors have other limitations for biomedical applications. Research on sensors that use piezoresistive or capacitive sensing technology has focused on silicon-based devices.

Silicon-based sensors are not well suited for many biomedical applications because they are mechanically brittle and typically cannot sustain large deformations and sudden impact. The substrates and encapsulating materials for many pressure sensors used for biomedical or robotic applications are made of plastics such as polyimide. Polyimide has an elastic modulus of 3-5 GPa. Skin has an elastic modulus of a few tens of kPa to several hundred kPa, i.e., the elasticity of skin is 4-5 orders of magnitude lower than the plastic materials that typically compose the bulk of an in-shoe pressure sensor. If such a sensor were implanted, the mismatch in mechanical properties of the sensor and the skin would result in patient discomfort and potentially inflammatory reactions of the body tissue. To summarize, the ultimate plantar pressure sensor should (a) have mechanical properties similar to human skin, (b) be capable of reliably and accurately measuring high (>1 Mpa) and low (<10 kPa) normal and shear pressures, and (c) have a low hysteresis, and negligible drift. While currently available sensors possess one or two of these properties, no sensor to date can achieve all these properties. To address these limitations of conventional pressure sensors, we propose to develop a pressure sensor that largely consists of two layers of a soft, biocompatible elastomer material that encapsulates one or more metallic conductors with a microcracked structure capable of measuring high magnitude normal and shear forces.

### BRIEF DESCRIPTION OF THE DRAWINGS

FIG. 1 is a simplified top view illustration of an embodiment of the resistive microcracked pressure sensor showing a single metallic conductor encapsulated in an elastomer substrate;

FIG. 2 is simplified side view illustration of the resistive microcracked pressure sensor of FIG. 1;

FIG. 3 is an image of the metal conductor with microcracks;

FIG. 4 is a graph illustrating the contribution of change in geometry and elongation of microcracks of the metallic conductor to resistance change while under strain;

FIGS. 5A-5G are illustrations showing one method for fabricating a resistive microcracked pressure sensor having a pair of metallic conductors;

FIG. 6 is a simplified illustration showing a top down view of the resistive microcracked pressure sensor after the deposition of the metallic conductors of FIGS. 5A-5G;

FIG. 7 is a simplified illustration showing a schematic design of the resistive microcracked pressure sensor and an experimental setup for measuring force/pressure perpendicular to a silicone surface of the resistive microcracked pressure sensor;

FIG. 8A is a graph illustrating resistance and normal force over 19 cycles of pressurizing and relaxation;

FIG. 8B is a graph illustrating resistance and normal force details over one cycle;

FIG. 9 is a graph illustrating a voltage drop and normal force of different magnitudes;

FIGS. 10A and 10B are graphs that illustrate a voltage drop across an embodiment of the resistive microcracked pressure sensor of FIG. 6 having two metallic conductors for detecting shear forces in the x-direction and y-direction, respectively;

FIGS. 11A and 11B are graphs that illustrate the difference in normalized resistance for the metallic conductors aligned in perpendicularly for shear forces in the x-direction and y-direction, respectively.

FIG. 12 is a simplified block diagram illustrating the basic components of the resistive microcracked pressure sensor;

FIG. 13 is a simplified top view illustration of the embodiment of the resistive microcracked pressure sensor of FIG. 6;

FIG. 14 is a simplified side view illustration of the resistive microcracked pressure sensor of FIG. 13; and

FIG. 15 is a simplified illustration showing one method for manufacturing the resistive microcracked pressure sensor of FIG. 14.

Corresponding reference characters indicate corresponding elements among the view of the drawings. The headings used in the figures do not limit the scope of the claims.

### DETAILED DESCRIPTION

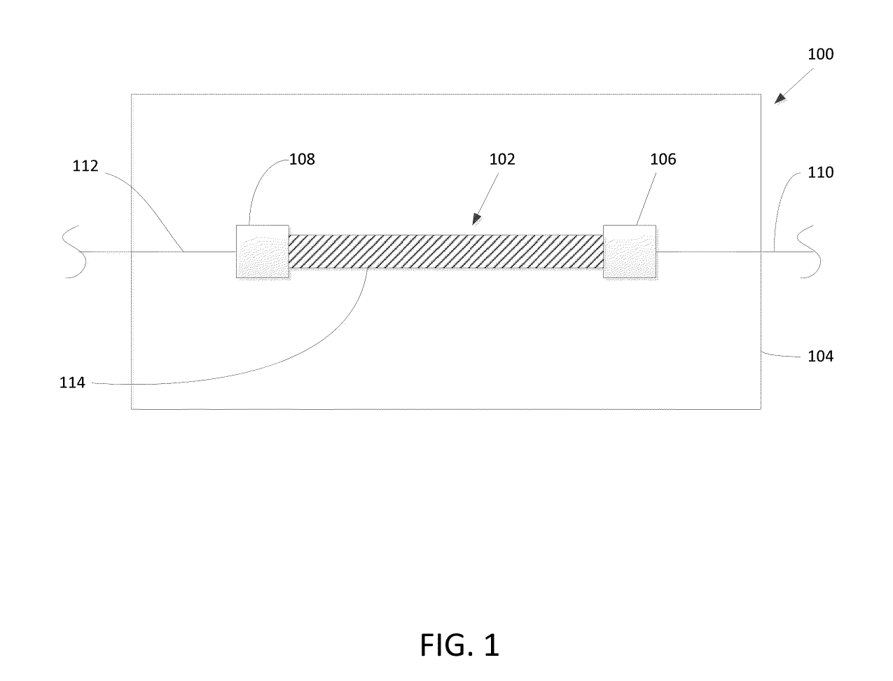

In general, embodiments of a resistive microcracked pressure sensor that provide for a system and method for measuring high and low magnitude normal and shear forces applied against an elastomer substrate based on the change in resistance detected from a metallic conductor encapsulated within the elastomer substrate of the pressure sensor are described herein. Referring to the drawings, embodiments of the resistive microcracked pressure sensor are illustrated and generally indicated as 100 and 200 in FIGS. 1-15.

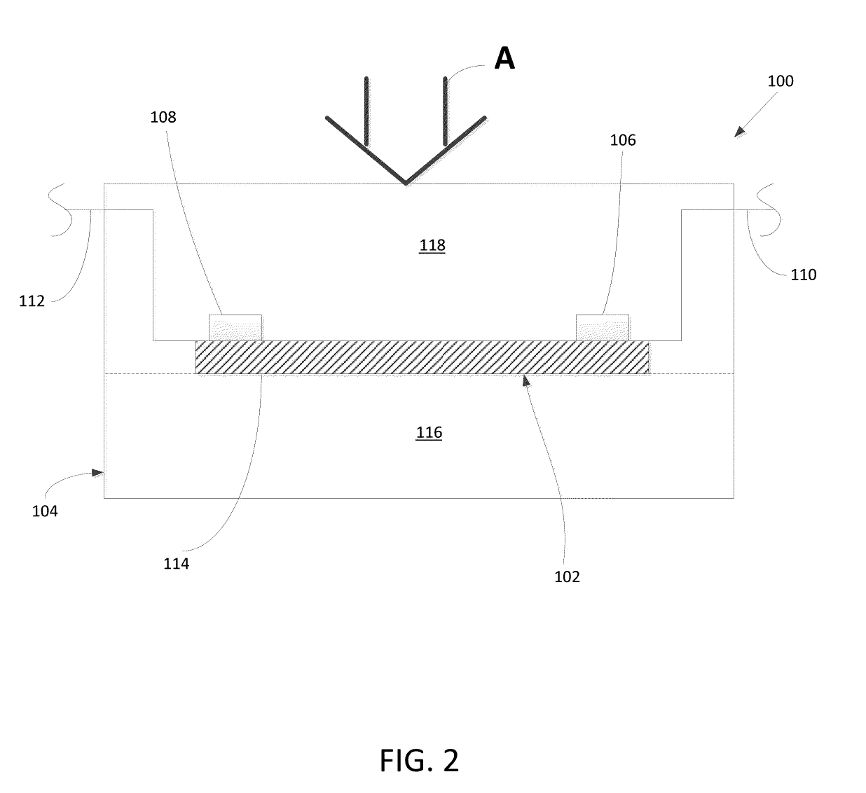

Referring to FIGS. 1 and 2, an embodiment of the pressure sensor, designated 100, may include an elastomer substrate 104 that encapsulates a metal stack 102 that includes a metallic conductor 114. In some embodiments, the metal stack 102 includes one or more other metallic materials, such as chromium and/or titanium to allow the metallic conductor 114 to adhere to the elastomeric substrate 104 during manufacture. The metallic conductor 114 is operatively connected to a measuring circuit 103 through first and second wires 110 and 112 connected to respective first and second contacts 106 and 108 attached to opposing ends of the metallic conductor 114. The measuring circuit 103 measures the change in voltage across the metallic conductor 114 to determine the change in resistance undergone by the metallic conductor 114 when normal and shear forces are applied to the elastomeric substrate 104 of the pressure sensor 100, thereby allowing the detection and measurement of the magnitude of the applied force.

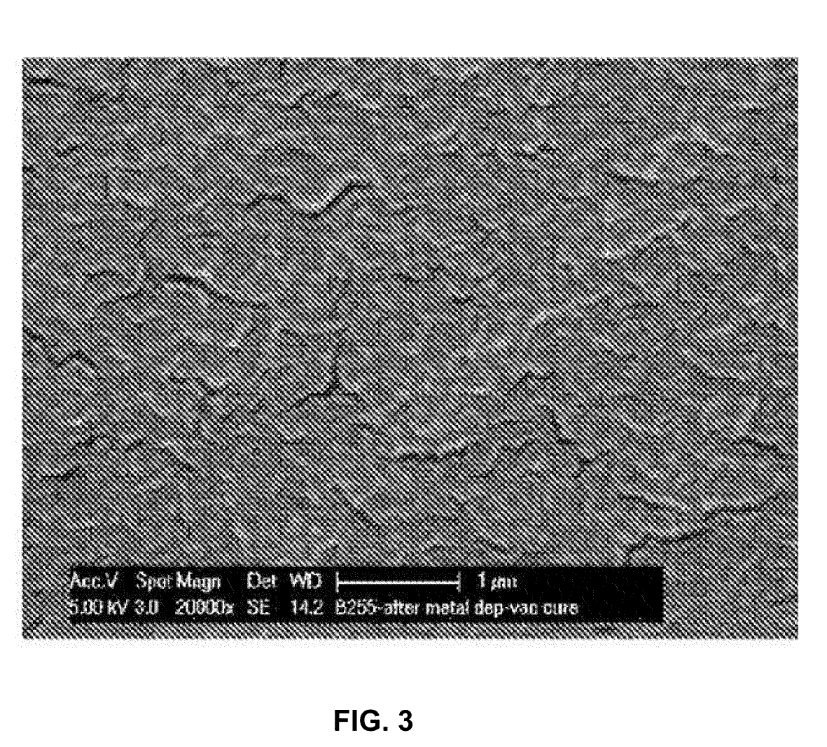

In one aspect, the metallic conductor 114 is manufactured to have a microcracked structure (FIG. 3) defining a plurality of microcracks most having a length of between 0.5-2 microns. As shall be discussed in greater detail below, it has been found that these microcracks increase the resistance of the metallic conductor 114 so that the pressure sensor 100 can detect and measure high magnitude forces that would otherwise fracture and render inoperable metallic conductors having a smooth and uniform structure without microcracks.

As shown in FIG. 2, the elastomer substrate 104 may include a lower elastomer layer 116 made of elastomer material that acts as a foundation during manufacture and an upper elastomer layer 118 also made of an elastomer material that is overlaid on the lower elastomer layer 116. During manufacture, the metallic conductor 114 is deposited and encapsulated between the lower and upper elastomer layers 116 and 118. In one embodiment, the lower and upper elastomer layers 116 and 118 may be made of an elastomer material, such as polydimethysiloxane (PDMS), although other suitable types of elastomer material are contemplated.

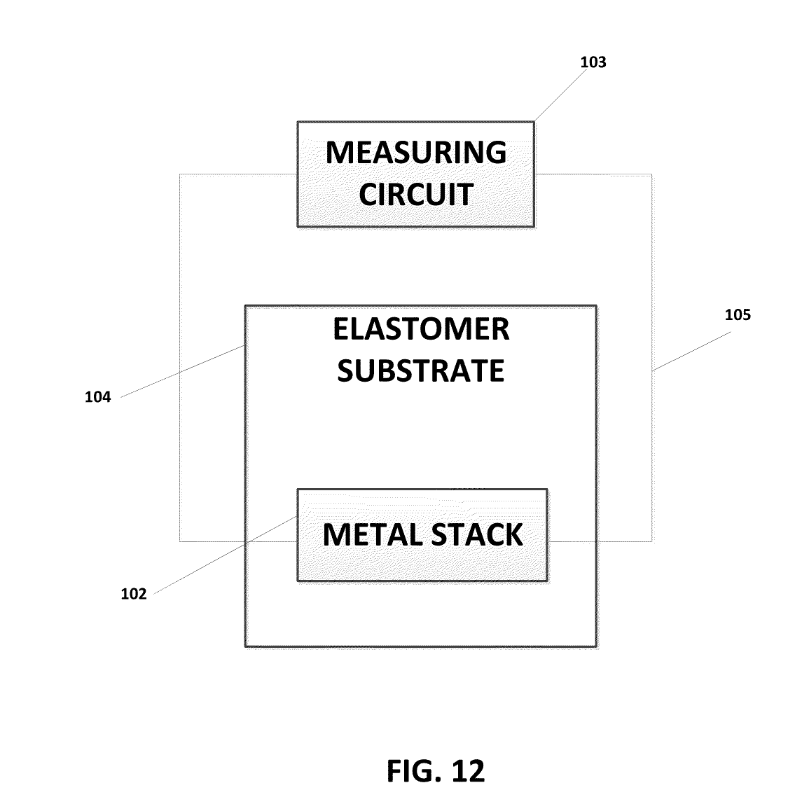

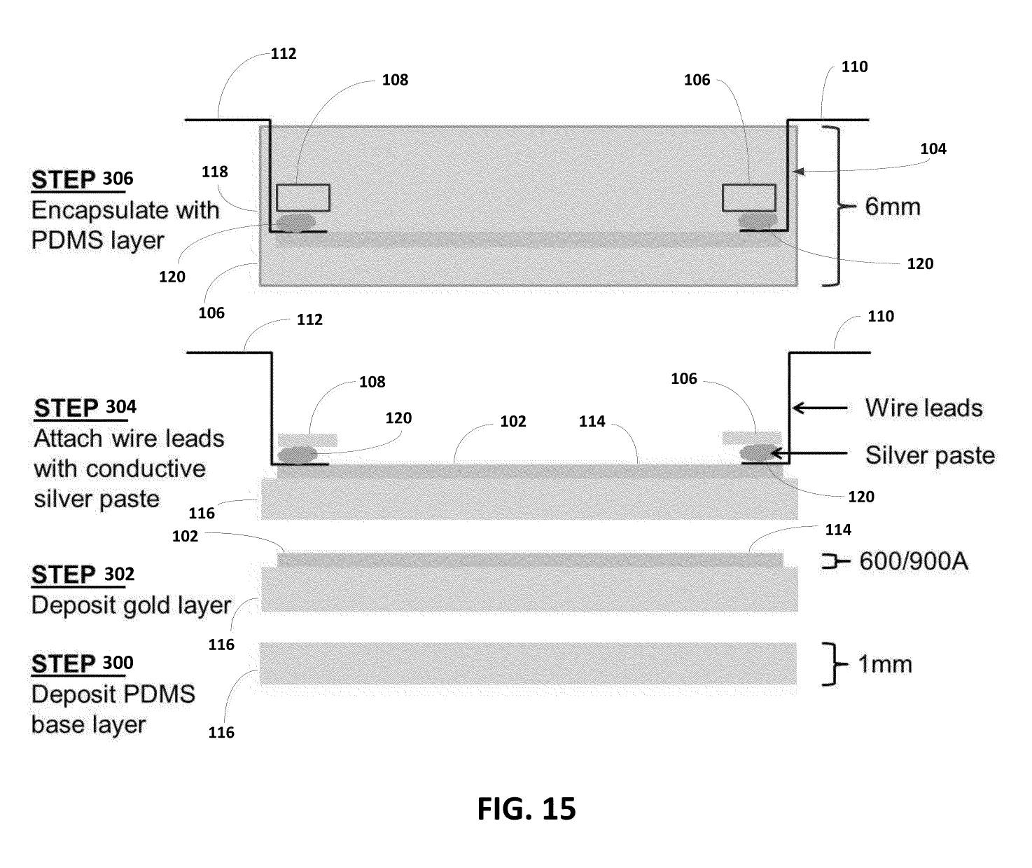

As shown in FIG. 15, a simplified illustration shows one method for manufacturing the pressure sensor 100. At step 300 depositing a lower elastomeric layer 116 for forming an elastomer substrate 104. At step 302, depositing a metal stack 102 having a metallic conductor 114, such as a gold film, on the lower elastomer layer 116. At step 304, attaching first and second wires 110 and 112 to the first and second contacts 106 and 108, respectively, by applying a conductive paste 120, such as a conductive silver paste, between the first contact 106 and the first wire 110 and between the second contact 108 and the second wire 112. At step 306, depositing an upper elastomer layer 118 over the lower elastomer layer 116 such that the metal stack 102 including the metallic conductor 114 are encapsulated within the elastomer substrate 104. Once the metal stack 114 is encapsulated, the first and second wires 110 and 112 of wire arrangement 105 are then operatively connected to the measuring circuit 103 (FIG. 12) to determine the magnitude of force A (FIG. 2) being applied to the pressure sensor 100.

In some embodiments, the pressure sensor 100 may be manufactured to have the following dimensions: lower elastomer layer 116 has a depth of about 1 mm; metallic conductor 114 has a depth of between 600 to 900 Å; upper elastomer layer 118 has a depth of about 5 mm, and the elastomer substrate 104 has an overall depth of about 6 mm.

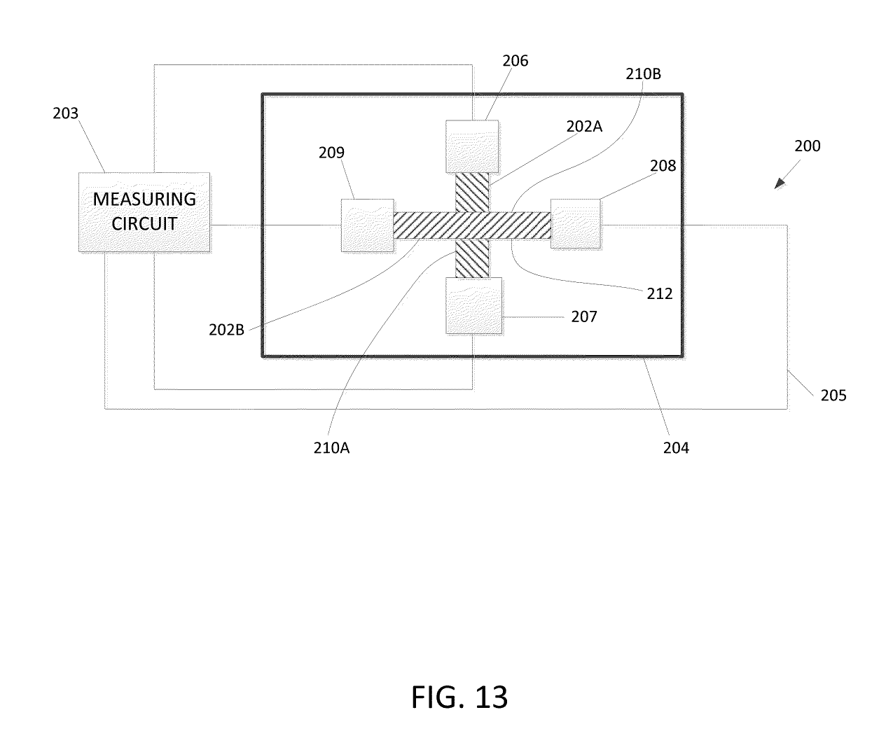

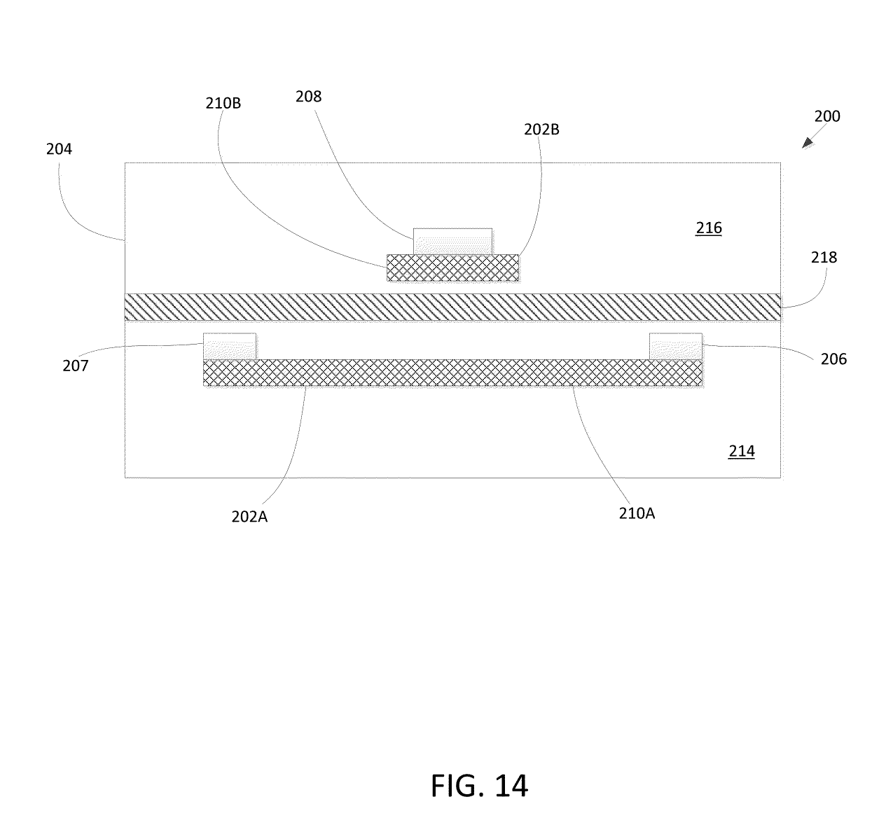

Referring to FIGS. 13 and 14, a second embodiment of the pressure sensor, designated 200, may include a first metal stack 202A and a second metal stack 202B encapsulated within an elastomer substrate 204. In one aspect, the first metal stack 202A includes a metallic conductor 210A that is oriented in perpendicular relation relative to a metallic conductor 210B of the second metal stack 202B as illustrated in FIG. 13. In one arrangement, the metallic conductor 210A includes a first contact 206 at one end of the metallic conductor 210A and a second contact 207 at the opposite end thereof, while the metallic conductor 210B includes a first contact 208 at one end of the metallic conductor 210B and a second contact 209 at opposite end thereof. As shown, a wiring arrangement 205 operatively connects each of the contacts 206-209 to a measuring circuit 203 that measures the change in voltage across the metallic conductors 210A and 210B for determining the change in resistance of each metallic conductor 210A and 210B. Similar to the metallic conductor 114, first and second metallic conductors 210A and 210B are formed during manufacture of the pressure sensor 200 with microcracks of about 1 micron that increase the overall resistance of the metallic conductors 210A and 210B such that the pressure sensor 200 can withstand and measure greater magnitudes of normal and shear forces.

As shown in FIG. 14, the elastomer substrate 204 comprises a lower elastomer layer 214 that acts as a foundation for deposition of the first metal stack 202A. In addition, an insulation layer 218 conductively insulates and physically separates the first metal stack 202A from the second metal stack 202B. Finally, an upper elastomer layer 216 encapsulates the second metal stack 202B between the upper elastomer layer 216 and the insulation layer 218.

The pressure sensors 100 and 200 have several advantages that would greatly improve in-shoe sensors, would provide a convenient and comfortable means of measuring contact forces on the skin using a body-worn pressure sensor, and could be made to be totally implantable:

1. Reduced mechanical mismatch: Matching the mechanical properties of the pressure sensor 200 with those of the tissue on the sole of the foot improves patient comfort and reduces the potential for inflammatory reactions. An estimated >99% of the thickness of the proposed pressure gage consists of two layers of silicone (the first layer is the substrate and the second layer is the outer encapsulation). Each of these two layers has an elastic modulus of about 1 MPa which is very close to the elastic modulus of skin and more than three orders of magnitude lower than currently available in-shoe sensors. The silicone substrate material is available in implantable medical grade making it suitable for implantations.

2. Improved precision and accuracy of pressure measurement. The precision and accuracy of the pressure measurement is of utmost importance for sensors used in robotics, prosthesis or biomedical rehabilitation devices. In the pressure gage of the pressure sensor 200, the electrical resistance of the metallic conductors 210 made of a deposited gold film sandwiched between the elastomer layers of the elastomer substrate 204 increases nearly linearly with strain. In addition, the slope of the increase is neither too large nor too small, thus pressure measurements are precise, and accurate over a large strain range.

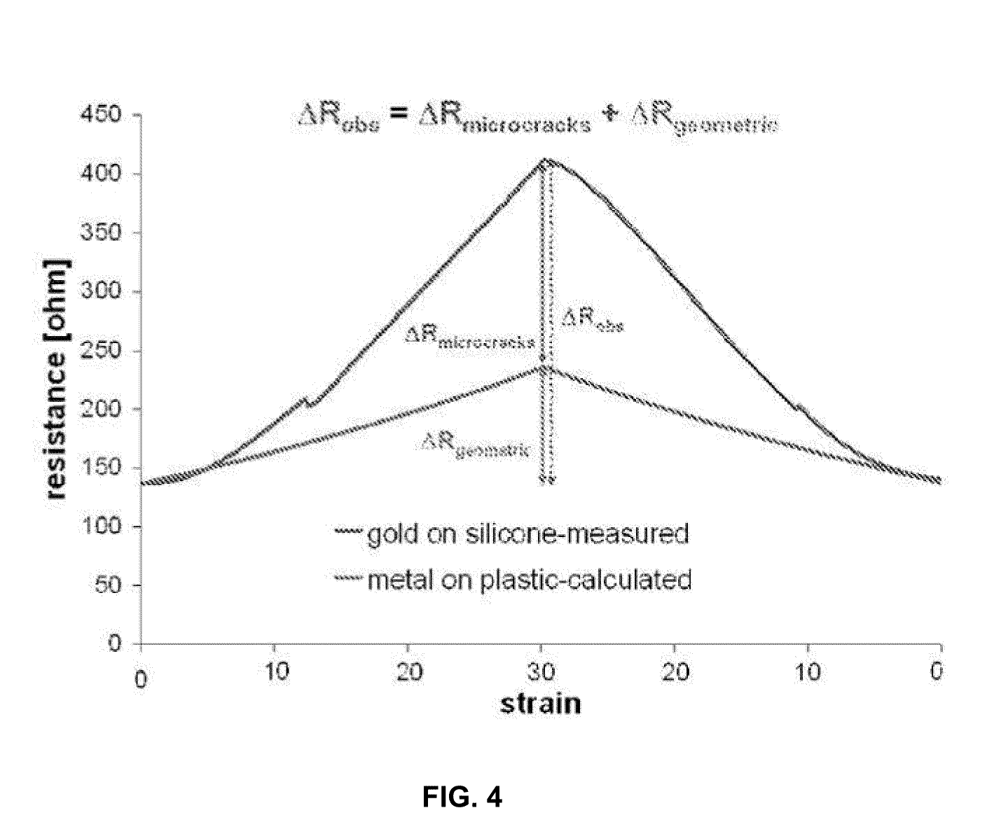

3. Improved sensitivity of pressure measurement. The gage factor F is used to quantify the sensitivity of a pressure/strain gage. The gage factor of the pressure sensor 200 is larger than that of the conventional metal gages. In some embodiments, the estimated gage factor for the resistive metal gage on elastomeric silicone is between 5 and over 20. The exact value depends on the dimensions of the metallic conductors 210. The gage factor for conventional metal gages is typically 2, but no more than 5. The increase in electrical resistance in these conventional pressure gages is mainly caused by changes in the physical dimensions of the metal under strain. The reason for the higher gage factor in the silicone-based gage of the pressure sensor 200 is that the increase in resistance under strain is not only caused by a change in the dimensions of the metallic conductor 210, but also by the lengthening of micro-cracks in the metal of the metallic conductor 210 (FIG. 3). Microcracks are a necessary requirement for elastically stretching straight metal conductors 210 beyond 10% strain. FIG. 4 shows a comparison of the resistance change for a hypothetical straight metal conductor on plastic and the measured resistance change for a metal conductor 210 on silicone for strains of up to 30%. The change in resistance for the metal conductor on plastic was calculated to illustrate the contributions of the microcracks in gold metallic conductors 210 on silicone to the measured R_{obs} (note that a real gold conductor on plastic cannot be elastically stretched to 30%). The total change in resistance under strain for gold on silicone R_{obs} equals the sum of the contribution from the change in dimensions of the gold film R_{geometric} and the elongation of microcracks R_{microcracks}. The substantial contribution of microcrack elongation to R_{obs} is the reason for the higher gage factor, and hence sensitivity, of the pressure gage for the pressure sensor 200 over resistive metal strain gages.

4. Improved shear force measurement normal and shear forces are two components of plantar pressure and both contribute to ulcer formation in the diabetic foot. To reduce or prevent ulcer formation, we need to be able to reliably measure these forces. Many pressure sensing technologies are capable of accurately and precisely measuring normal forces. However, measuring shear forces is considerably more challenging. Currently available shear force sensors often require complicated computations to extract the applied shear force which limits their applicability in clinical settings. In addition, these sensors are typically made of brittle, semiconducting materials such as silicon, which further limits their usability for biomedical applications.

In addition, measuring shear forces is considerably more challenging since currently available shear force sensors often require complicated computations to extract the applied shear force which limits their applicability in clinical settings. In addition, these sensors are typically made of brittle, semiconducting materials such as silicon, which further limits their usability for biomedical applications.

The pressure sensor 200 has exhibited the following properties: (1) accurate and precise measurement of normal pressure as well as shear forces, (2) high repeatability of the measurement, (3) no hysteresis, and (4) being soft and compliant. Embodiments of a silicone-based pressure sensor 200 described herein possess these properties.

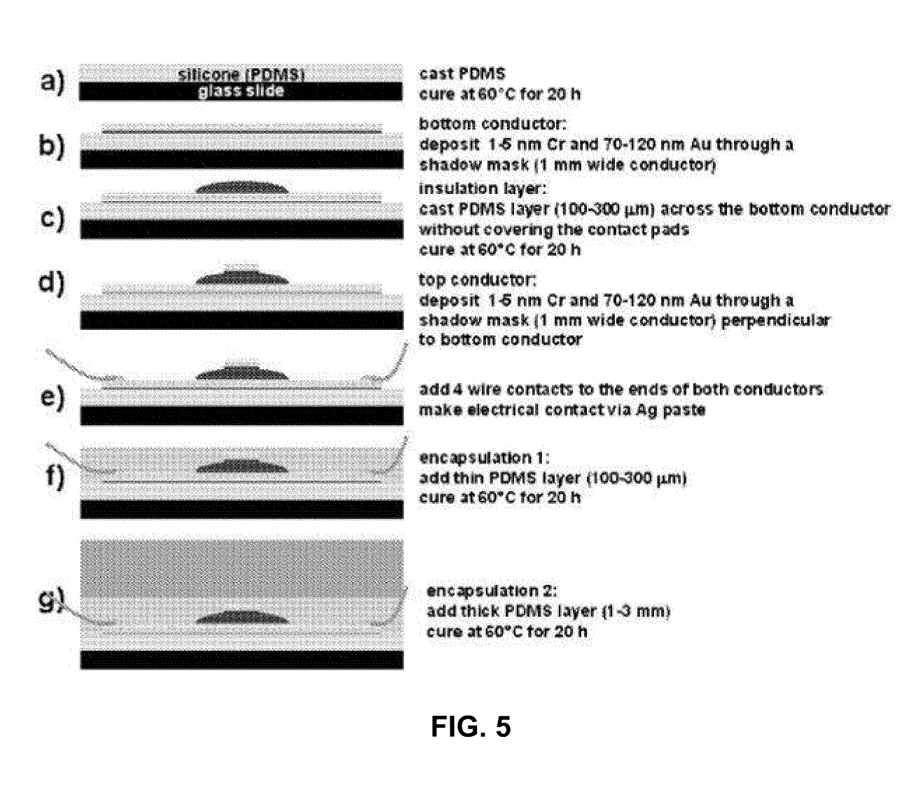

In one embodiment, the entire pressure sensor 200 includes a soft elastomer poly(dimethylsiloxane) (PDMS, Sylgard 184, Dow Corning), a thin (<120 nm) Au film or metallic components 210A and 210B, and an adhesion layer (Cr or Ti, 1-5 nm thick) in contact with the Au film. The use of PDMS as an elastomer substrate 204 has a number of advantages. In particular, PDMS is chemically inert, elastically stretchable to >100% strain, biocompatible and thermally stable (from −55 to 200 degree celsius). It is available in implantable grade from different suppliers and has an elastic modulus similar to human skin (tunable from an elastic modulus <0.5 MPa to >5 MPa). FIGS. 5A-5G illustrate the process sequence for fabricating the pressure sensor 200. The silicone is mixed from the prepolymer and the cross linker in a 10:1 ratio by weight, degassed, spun on or cast, and cured (FIG. 5A). The first metal stack 202A (the bottom metallic conductor 210A) of 1-5 nm Cr or Ti, 70-120 nm of gold is deposited through a shadow mask on the lower elastomer layer 214 that acts as a foundation by electron beam evaporation, thermal evaporation, or sputtering (FIG. 5B). In the alternative, the patterning of the metal stack 202A, for example the golf film or other similar metallic conductor 210A, may be accomplished through photolithography. An upper elastomer layer 216 of PDMS (the insulation layer) is then cast across the center of the gold film of the metallic conductor 210A, and cured (FIG. 5C).

A second metal stack 202B (the top conductor 210B) of 1-5 nm Cr or Ti, <120 nm of gold is deposited through a shadow mask by electron beam evaporation, thermal evaporation, or sputtering (FIG. 5D). This second metal stack 202B has a perpendicular orientation to the first metal stack 210A and 210B. The PDMS insulation layer 218 electrically insulates the metallic conductors 210A and 210B of the first and second metal stacks 202A and 202B. A wire arrangement 205 made of gold is attached to the respective contacts 206-209 of the gold metallic conductors 210 using conductive silver paste 120 for improved electrical contact and a PDMS pad for improved mechanical stability (FIG. 5E). For mechanical protection and electrical insulation, the entire pressure sensor 200 is encapsulated between lower and upper elastomer layers 214 and 216 of the PDMS elastomer substrate 204, a thin one (100-300 m, FIG. 5F) followed by a thick one (up to several mm, FIG. 5G). After completing the cure at 60° C. for 24 h, the completed pressure sensor 200 is removed from the glass slide.

There are two important factors for the pressure sensor 200 to function properly:

1. Morphology of the gold metallic conductor—The gold metallic conductors 210A and 210B must have a micro-cracked morphology (FIG. 3), which limits the maximum thickness of the Au film that comprises the gold metallic conductor 210A and 210B.

2. Thickness ratio of PDMS substrate: Au—The thickness of the insulation layer 218 and the lower and upper elastomer layers 214 and 216 that encapsulate the insulation layer 218 must be carefully chosen for the gold metallic conductors 210A and 210B to remain electrically conducting. If the PDMS covering the gold metallic conductors 210A and 210B are thicker than about 0.5 mm, both thick (>70 nm) and thin (20-50 nm) gold metallic conductors 210A and 210B will lose their electrical conduction after the PDMS substrate 204 is cured, rendering the resistive microcracked sensor 200 non-functioning. If the PDMS substrate 204 covering the gold metallic conductors 210A and 210B are 100-300 μm thick, only the thin (20-50 nm) gold metallic conductors 210A and 210B lose their electrical conduction whereas the thicker gold metallic conductors 210A and 210B remain electrically conducting. This finding is important for the fabrication of the pressure sensor 200. The minimum required thickness of the gold metallic conductors 210A and 210B for the pressure sensor 200 to function properly depends on the thickness of the overlying silicone: the thicker the silicone layer, the thicker the gold metallic conductors 210A and 210B must be. In one embodiment of the biomimetic pressure sensor, the gold metallic conductors 210A and 210B must have a minimum thickness (>70 nm), and the thickness of the PDMS substrate 204 that the gold metallic conductors 210A and 210B are in contact with before curing must generally be less than about 0.5 mm. For this reason, two encapsulation layers are required after the second gold deposition: (i) a thin encapsulation layer (100-300 μm) that is first cured to allow the gold metallic conductor 210A underneath to become stable, and (ii) a thick encapsulation layer that protects the first layer and then brings the pressure sensor 200 to the desired overall dimension.

### Testing

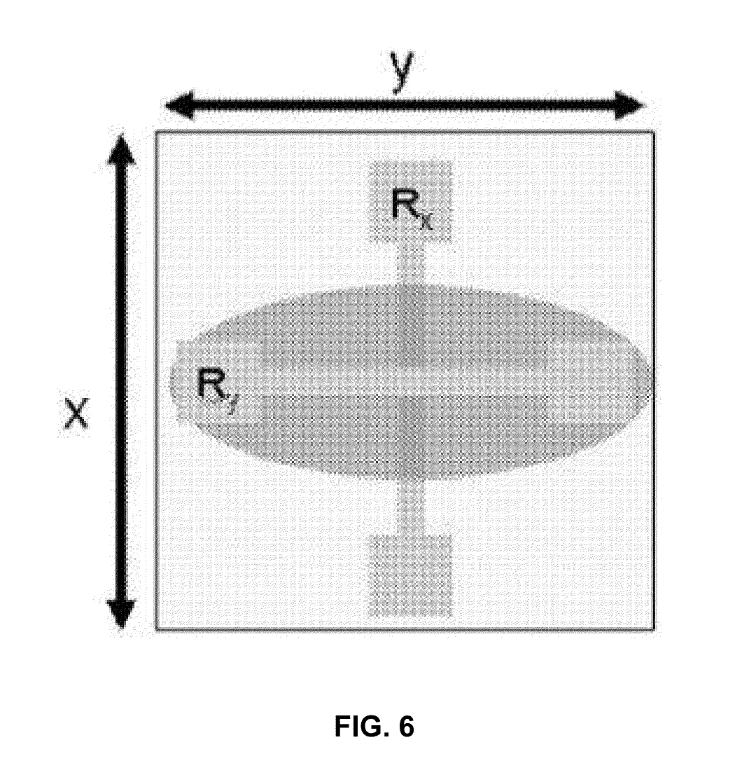

The capability of this “skin-like” resistive microcracked pressure sensor 200 to measure normal and shear forces was evaluated. The two perpendicularly-oriented gold metallic conductors 210A and 210B represent the actual pressure/force sensing element. Each metallic conductor 210A and 210B is 20 mm long and 1 mm wide with 4 mm×4 mm wide pads to which the electrical contact is made (FIG. 6). The resistance of each gold conductors 210A and 210B increases with the applied pressure/force. The normal force has a larger contribution to the overall resistance increase than shear forces. Thus, if only one conductor 210A or 210B are used, the resistance change due to the applied normal force dominates, making shear force measurements imprecise. To reduce/eliminate the contributions of normal forces, thus allowing precise shear force measurements, two perpendicular and electrically insulated conductors are required (FIG. 6), whose resistance is measured independently. The normal forces that are applied to the perpendicularly-oriented metallic conductors 210A and 210B are the same, thus, their contribution can be eliminated by taking the difference in the normalized resistance of the two metallic conductors 210A and 210B. The resulting difference is a measure of the shear force in x- or y-direction because the resistance increase of the conductors 210A and 210B depends on whether the force is along or perpendicular to its axis.

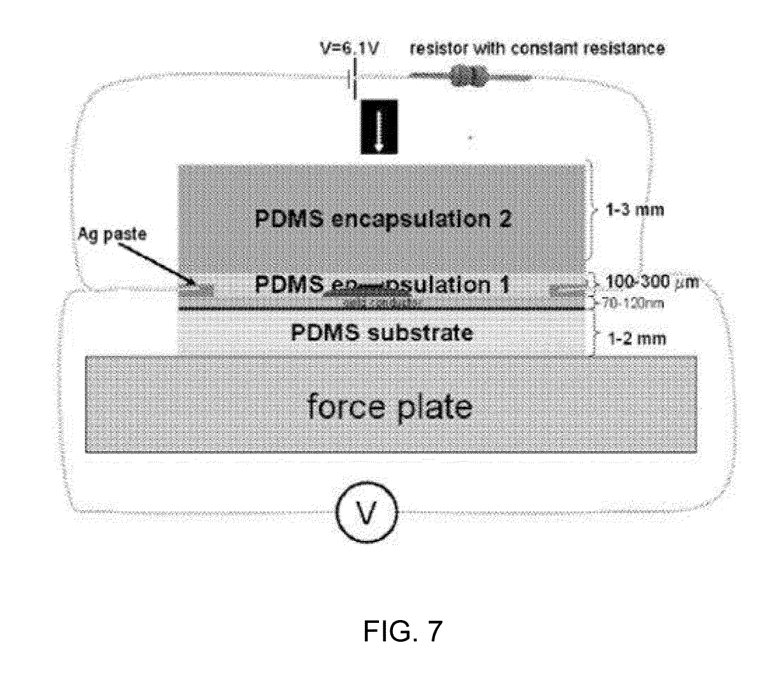

We used the setup described in FIG. 7 to measure the resistance vs. force characteristic of the pressure sensor 200. The pressure sensor 200 was placed on a force plate that is able to measure the three components of applied force: normal force (z-direction), and shear forces (x- and y-directions). The resistance of the pressure sensor 200 is measured using a voltage divider circuit. Measuring the voltage drop across the pressure sensor 200 allows us to calculate its resistance.

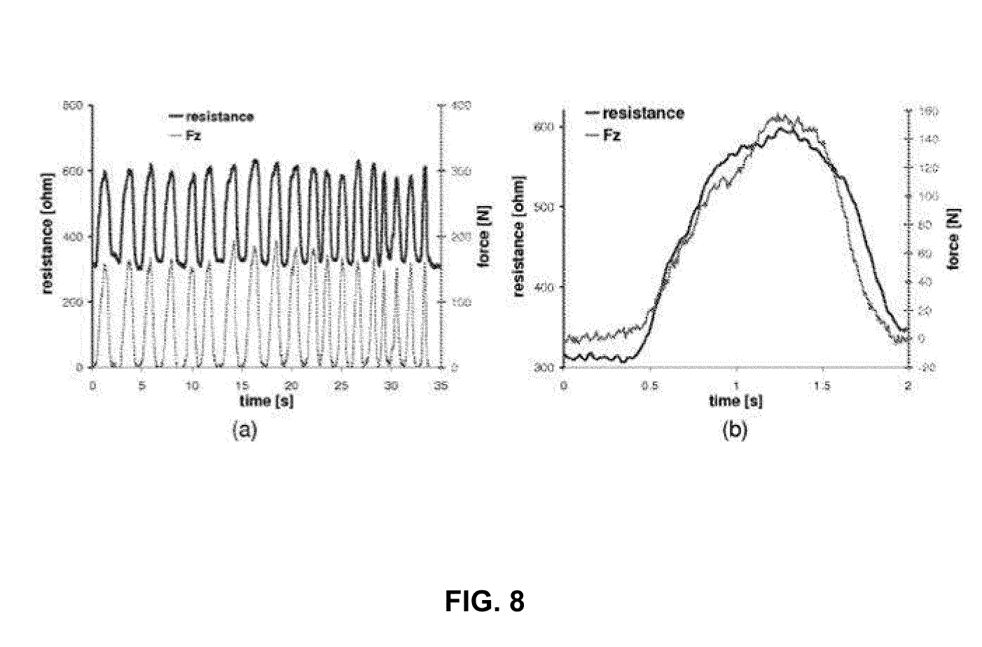

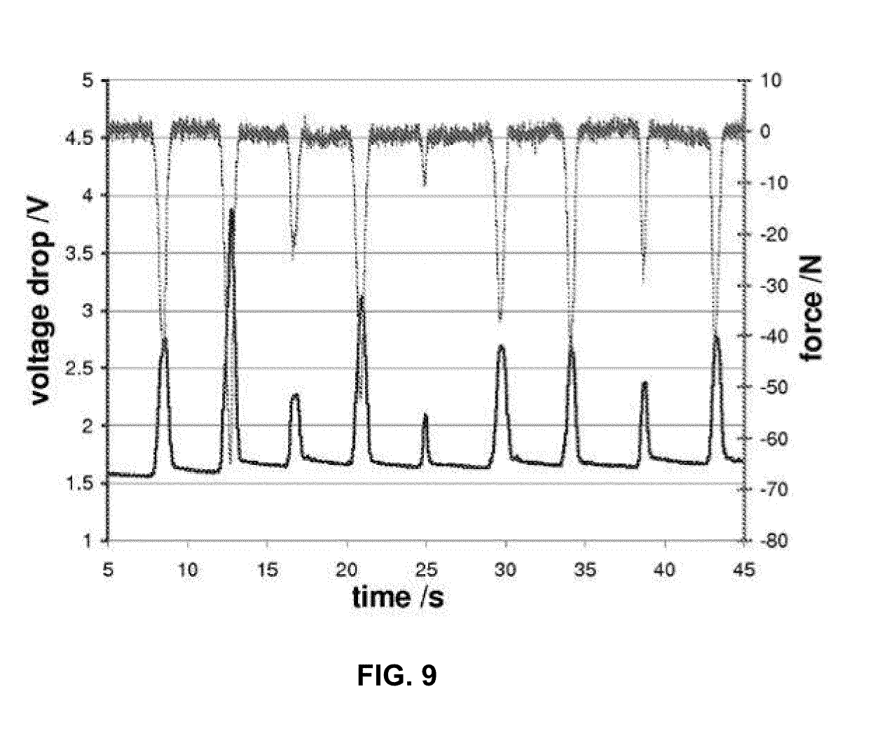

FIG. 8A shows a plot of the resistance and the normal force over 19 cycles of manually pushing down a round metal cylinder on top of the silicone surface, followed by removal of the applied force. The metal cylinder had a radius of 6.7 mm and a normal force of 100 N, therefore corresponds to a pressure of 709 kPa, or 103 psi. In addition, the graph shown in FIG. 8B illustrates the resistance of the pressure sensor 200 very closely follows the applied force. There is no hysteresis or drift. The intervals between peak forces are 1-2 s and the resistance always returns to the original level. Even shorter intervals are likely to be resolved. The increase/decrease of the resistance is very swift because the metal conductor stretches and relaxes elastically over a large pressure range. FIG. 9 shows that the resistance change in a metallic conductor 210 is proportional to the applied force.

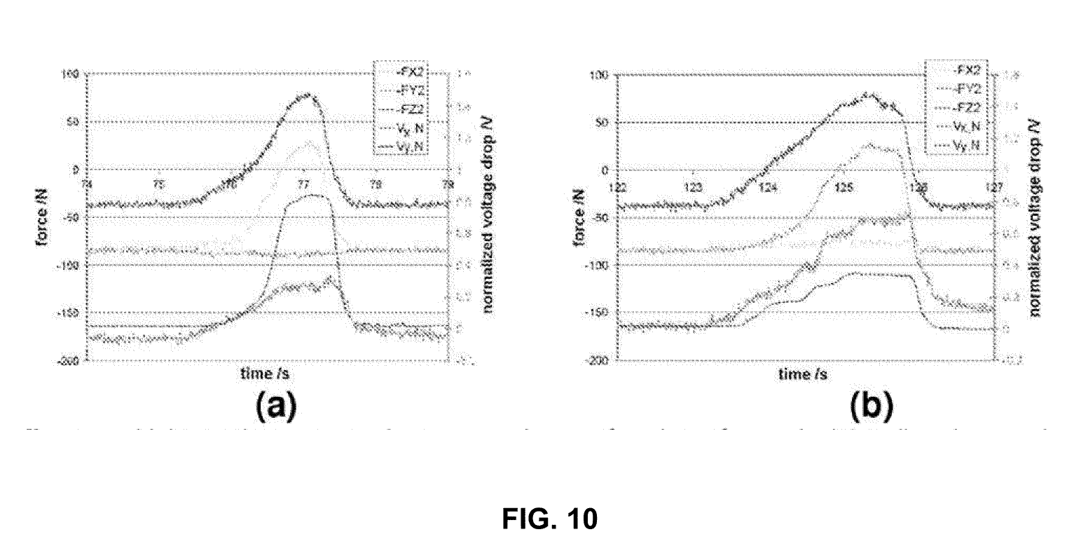

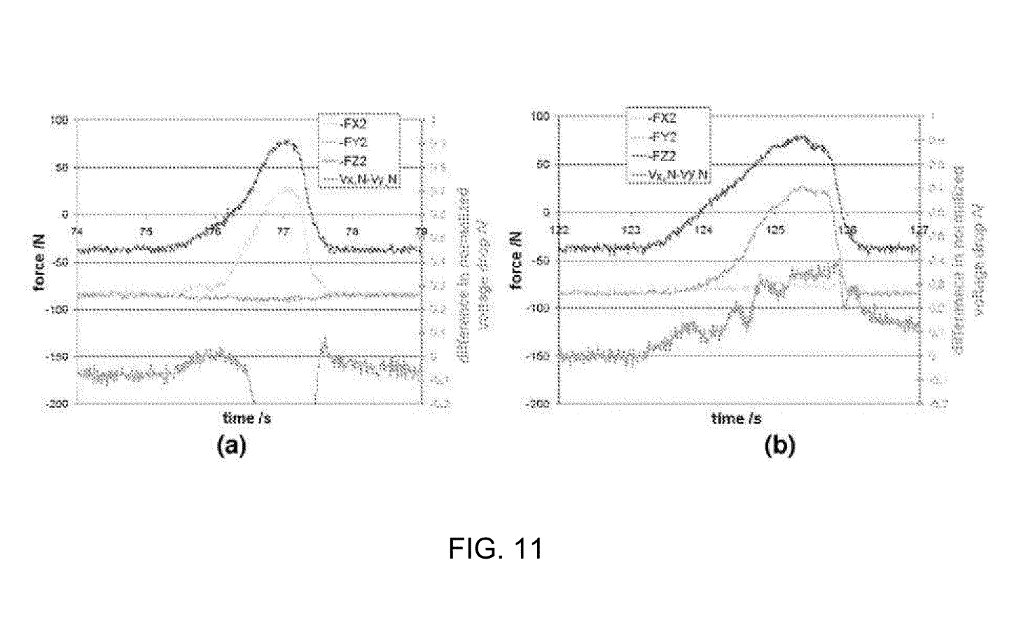

FIGS. 10A and 10B show the normalized resistance change for the two metallic conductors 210A and 210B when shear force is applied in x-direction (FIG. 10A) and y-direction (FIG. 10B), respectively. The normal force has a similar impact on the normalized resistance across both metallic conductors 210A and 210B. Thus, subtracting the resistance of the metallic conductor 210 aligned in x-direction from the resistance of the metallic conductor 210 aligned in y direction (or vice verse) eliminates the contribution of the normal force to the change in resistance. The graphs in FIGS. 11A and 11B plot the difference in resistance of the two conductors for shear force in x-direction (FIG. 11A), and shear force in y-direction (FIG. 11B). The normal force has a similar value (70 N) for both measurements. When shear force is applied in x-direction (FIG. 11A), the resistance increase for the metallic conductor 210 aligned in y-direction is larger than for the metallic conductor 210 aligned in x-direction, thus, the difference in resistance (or voltage drop) is negative. When shear force is applied in x-direction (FIG. 11B), the resistance increase for the metallic conductor 210 aligned in y-direction is larger than for the metallic conductor 210 aligned in x-direction, thus, the difference in resistance is positive. These measurements clearly demonstrate the capability of the pressure sensor 200 to measure shear forces.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A method for manufacturing a resistive pressure sensor comprising:
depositing a first metal stack having a metallic conductor on a lower elastomer layer such that a plurality of microcracks are formed by the metallic conductor;
attaching pair of contacts and a wiring arrangement to the metallic conductor; and
depositing an upper elastomer layer over the first metal stack such that the first metal stack is encapsulated between the lower and upper elastomer layers.

2. The method of claim 1, wherein the first metal stack comprises at least one of a chromium material, a titanium material and/or a gold material.

3. The method of claim 2, wherein the chromium material and/or titanium material has a thickness between 1 to 5 nm.

4. The method of claim 2, wherein the gold material has a thickness of between 70 to 120 nm.

5. The method of claim 1, wherein the first metal stack is deposited through either a shadow mask or a photolithography technique.

6. The method of claim 5, wherein the first metal stack is deposited through the shadow mask by electron beam evaporation, thermal evaporation, or sputtering.

7. The method of claim 1, further comprising:
curing the first metal stack that has been encapsulated.

8. The method of claim 7, wherein the first metal stack is cured at 60 degrees centigrade for 24 hours.

9. The method of claim 1, wherein the lower elastomer layer and the upper elastomer layer are made from poly(dimethylsiloxane).

10. The method of claim 1, further comprising:
casting an insulation layer on the first metal stack; and
depositing a second metal stack on the insulation layer;
wherein deposition of the upper elastomer layer encapsulates the first metal stack, the insulation layer, and the second metal stack.

11. The method of claim 10, wherein the insulation layer is made from poly(dimethylsiloxane).

12. The method of claim 10, wherein the insulation layer is caste between the first metal stack and the second metal stack.

13. The method of claim 10, wherein the first metal stack is oriented in perpendicular relation relative to the second metal stack.

14. The method of claim 10, wherein the insulation layer insulates the first metal stack from the second metal stack.

15. The method of claim 1, wherein the wire arrangement is operatively connected to a measuring circuit for measuring the change in voltage across the metallic conductor for determining the magnitude of force applied to the pressure sensor.

16. A pressure sensor comprising:
an elastomer substrate;
a first metal stack encapsulated within the elastomer substrate, the first metal stack having a metallic conductor defining a plurality of microcracks;
first and second contacts operatively connected to each respective end of the metallic conductor; and
a wiring arrangement operatively connected between the first and second contacts and a measuring circuit for measuring the change in voltage across the metallic conductor.

17. The pressure sensor of claim 16, wherein the elastomer substrate defines a lower elastomer layer and an upper elastomer layer that encapsulates the first metal stack.

18. The pressure sensor of claim 17, further comprising:
an insulation layer formed between the lower elastomer layer and the upper elastomer layer.

19. The pressure sensor of claim 18, further comprising:
a second metal stack including a second metallic conductor, the second metal stack being encapsulated between the insulation layer and the upper elastomer layer;
wherein the first metal stack is encapsulated between the insulation layer and the lower elastomer layer.

20. The pressure sensor of claim 19, wherein the first metal stack and the second metal stack are oriented in perpendicular relation relative to each other.

21. The pressure sensor of claim 19, wherein the first metal stack and the second metal stack comprise at least one of a chromium material, a titanium material and/or a gold material.

22. The pressure sensor of claim 21, wherein the chromium material and/or titanium material has a thickness between 1 to 5 nm.

23. The pressure sensor of claim 21, wherein the gold material has a thickness of between 70 to 120 nm.

24. The pressure sensor of claim 16, wherein each of the plurality of microcracks has a length of between 0.5 to 2 microns.

25. The method of claim 16, wherein the elastomer substrate comprises a thick layer and a thin layer.

26. The method of claim 25, wherein the thin layer has a thickness in a range of between 100 to 300 μm.

27. The method of claim 25, wherein the thick layer has a maximum thickness of 2 mm.
